(19) United States
(12) Patent Application Publication
(10) Pub. No.: US 2019/0049189 A1
(43) Pub. Date: Feb. 14, 2019

(54) COOLING APPARATUS FOR ELECTRONIC DEVICE WITH VAPOR-LIQUID PUMP

(71) Applicant: ZALMAN TECH CO., LTD., Ahnyang-si (KR)

(72) Inventor: Kukyoung Yoon, Seoul (KR)

(21) Appl. No.: 16/161,291

(22) Filed: Oct. 16, 2018

Related U.S. Application Data
(63) Continuation of application No. PCT/KR2017/004005, filed on Apr. 13, 2017.

(30) Foreign Application Priority Data
Apr. 19, 2016 (KR) 10-2016-0047602

(51) Int. Cl. F28D 15/02; F28D 15/06; H01L 23/427; H05K 7/20

(52) U.S. Cl. CPC F28D 15/0266; F28D 15/06; F28D 1/047; H05K 7/20663; F28D 15/0241; H01L 23/427

(57) ABSTRACT

An electronic device cooling apparatus equipped with a vapor-liquid pump, including: an impeller located in a vapor-liquid receiving part that receives a vapor-liquid; a motor stator which is located outside separated from the vapor-liquid receiving part and transfers the driving force to the impeller; a sealed injection cover, in which an impeller shaft is formed on one side; a motor stator insertion rod, which is formed to protrude from the axis to the outer center of the impeller shaft such that the motor stator is inserted thereinto, is formed on the other side; a top plate, which is formed by extending from an edge of the motor stator insertion rod to separate the impeller from the motor stator, is formed; and an inlet through which the vapor-liquid flows in and an outlet through which the vapor-liquid flows out are formed on one side of the top plate; a heat transfer base, which is fused or attached to the bottom of the impeller along the rim of the top plate such that the vapor-liquid receiving part is formed; an inlet pipe, which is fused or attached to the inlet such that the vapor-liquid is flowed in; an outlet pipe, which is fused or attached to the outlet such that the vapor-liquid is flowed out; and a condenser, which is located between the inlet pipe and the outlet pipe and condenses the gas in the vapor-liquid, wherein the inner space, which is a closed loop that leads to the vapor-liquid receiving part, the inlet pipe, the outlet pipe and the condenser, forms a vacuum.

### REFERENCE TO RELATED APPLICATIONS

This is a continuation of International Patent Application PCT/KR2017/004005 filed on Apr. 13, 2017, which designates the United States and claims priority of Korean Patent Application No. 10-2016-0047602 filed on Apr. 19, 2016, the entire contents of which are incorporated herein by reference.

### FIELD OF THE INVENTION

The present disclosure relates to an electronic device cooling apparatus, and more specifically, to an electronic device cooling apparatus which is equipped with a vapor-liquid pump capable of efficiently cooling using the vapor-liquid pump.

### BACKGROUND OF THE INVENTION

Electronic devices or electronic components, such as a processor, are highly temperature-sensitive with regard to their performances. The temperature range for best performance has a very limited range, and thus, the management of heat energy for these electronic devices is a critical part of performance management.

Currently, a variety of electronic device cooling apparatuses are being studied for improving the speed and performance of electronic devices, and cooling apparatuses such as air-cooling or water-cooling systems are mostly mass-produced and used. However, these conventional cooling apparatuses have limited performance in electronic device heat dissipation, and studies on electronic device cooling apparatuses with higher cooling capacity are being continued.

In particular, the air cooling system has limitations because it raises another problem by merely increasing the size of the fan or the heat dissipation area of the heat sink, whereas the water cooling system has limitations because it utilizes the specific heat of the single-phase working fluid (coolant).

In order to overcome the above-mentioned problems and limitations and to have a greater cooling capacity, U.S. Patent Application Publication No. 2003/0205364 A1 discloses a two-phase cooling system of a liquid and a gas. However, the two-phase cooling system has the advantage of not using a pump, but it had the disadvantage of not being able to rapidly circulate the working fluid.

Therefore, there is a need to introduce a new type of an electronic device cooling apparatus that can further enhance the advantages of the two phases while applying a two-phase cooling system.

### SUMMARY OF THE INVENTION

The present invention has been made in view of the above-described need, and an object of the present invention provides an electronic device cooling apparatus equipped with a vapor-liquid pump capable of constituting the vapor-liquid pump while applying a two-phase cooling system.

In addition, another object of the present invention provides an electronic device cooling apparatus equipped with a vapor-liquid pump capable of pumping a two-phase cooling material (i.e., vapor-liquid) while maintaining a vacuum state.

An object of the present invention as described above can be achieved by providing an electronic device cooling apparatus equipped with a vapor-liquid pump, which includes: an impeller located in a vapor-liquid receiving part that receives a vapor-liquid; a motor stator which is located outside separated from the vapor-liquid receiving part and transfers the driving force to the impeller; a sealed injection cover, in which an impeller shaft, which is formed to protrude to the center of the vapor-liquid receiving part such that the impeller is inserted thereinto, is formed on one side; a motor stator insertion rod, which is formed to protrude from the axis to the outer center of the impeller shaft such that the motor stator is inserted thereinto, is formed on the other side; a top plate, which is formed by extending from an edge of the motor stator insertion rod to separate the impeller from the motor stator, is formed; and an inlet through which the vapor-liquid flows in and an outlet through which the vapor-liquid flows out are formed on one side of the top plate; a heat transfer base, which is fused or attached to the bottom of the impeller along the rim of the top plate such that the vapor-liquid receiving part is formed; an inlet pipe, which is fused or attached to the inlet such that the vapor-liquid is flowed in; an outlet pipe, which is fused or attached to the outlet such that the vapor-liquid is flowed out; and a condenser, which is located between the inlet pipe and the outlet pipe and condenses the gas in the vapor-liquid, in which the inner space, which is a closed loop that leads to the vapor-liquid receiving part, the inlet pipe, the outlet pipe and the condenser, forms a vacuum.

Additionally, the top plate forms a recess into which the motor stator is inserted and seated, and the impeller may include a magnet which is formed to surround the recess with the top plate interposed therebetween and receives power from the motor stator.

Additionally, the amount of the liquid forming the vapor-liquid at room temperature may be in the amount of 50% to 90% relative to the internal space, which is a closed loop.

Further, the liquid forming the vapor-liquid may be one which cools an electronic device using specific heat and the latent heat of evaporation by fluid phase change.

According to an embodiment of the present invention as described above, the electronic device cooling apparatus of the present invention has an effect that the vapor-liquid pump can be constructed while applying the two-phase cooling system, and thus the cooling efficiency can be maximized.

Additionally, the electronic device cooling apparatus of the present invention has an effect that thermal cycling can be promoted by pumping the vapor-liquid (i.e., a two-phase coolant), and the impeller can easily receive a driving force transmitted from an external motor and is able to pump the vapor-liquid.

### BRIEF DESCRIPTION OF THE DRAWINGS

FIG. 1 is an exploded perspective view illustrating an electronic device cooling apparatus according to an embodiment of the present invention;

FIG. 2 is a plan view illustrating an electronic device cooling apparatus according to an embodiment of the present invention;

FIG. 3 is a cross-sectional view taken along the B-B direction in FIG. 2;

FIG. 4 is a cross-sectional view taken along the C-C direction in FIG. 2; and

FIG. 5 is a diagram illustrating the entire system of an electronic device cooling apparatus according to an embodiment of the present invention.

### DETAILED DESCRIPTION OF THE INVENTION

In the following description of the present invention, a detailed description of known functions and configurations incorporated herein will be omitted when it is determined that the detailed description may unnecessarily obscure the gist of the present invention. In addition, the terminologies used herein are terms used to appropriately represent preferred embodiments of the present invention, which may vary depending on the user, intention of the operator, or custom in the field to which the present invention pertains, etc. Accordingly, the definition of these terms should be determined based on the contents throughout the present specification. The same reference numeral in each drawing refers to the same component.

<Electronic Device Cooling Apparatus>

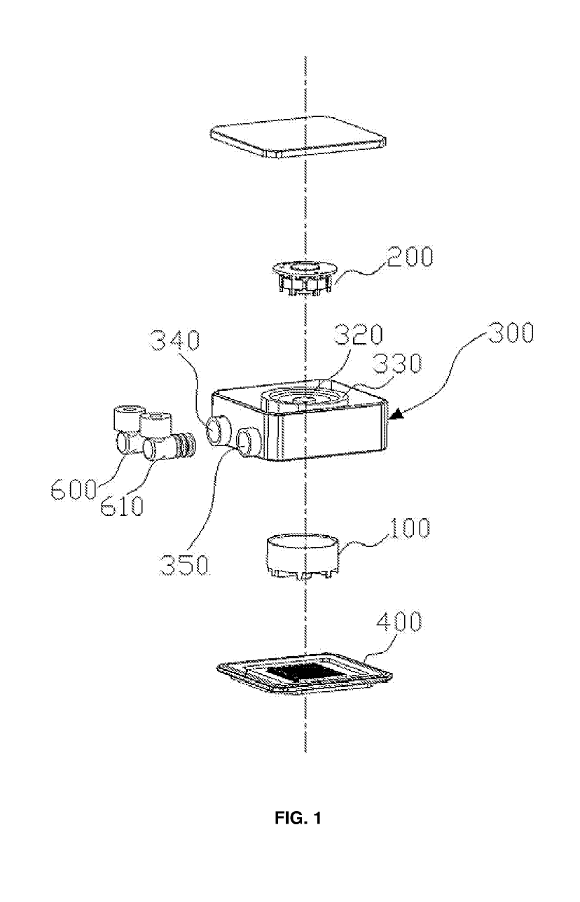

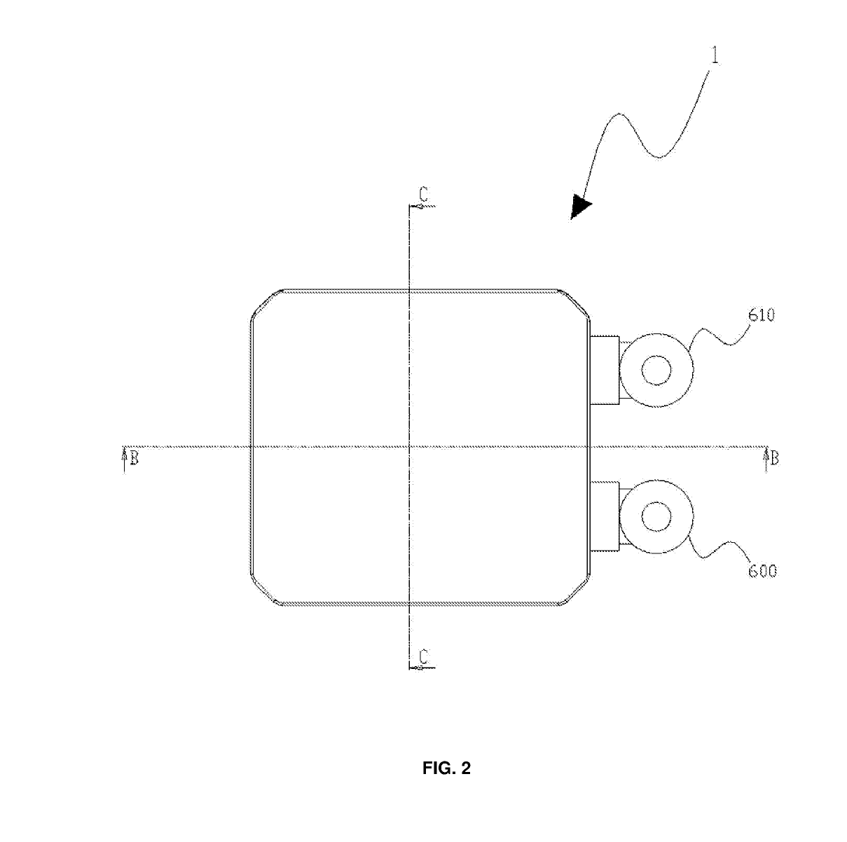

FIG. 1 is an exploded perspective view illustrating an electronic device cooling apparatus according to an embodiment of the present invention; and FIG. 2 is a plan view illustrating an electronic device cooling apparatus according to an embodiment of the present invention. As illustrated in FIGS. 1 and 2, in an embodiment, the electronic device cooling apparatus may be constituted to include a sealed injection cover 300 in which an impeller shaft 310, a motor stator insertion rod 320, and a top plate 330 are formed in an integrated manner; an impeller 100 located below the sealed injection cover 300; a motor stator 200 located above the sealed injection cover 300; and a vapor-liquid pump 1, which is formed such that a heat transfer base 400, which is fused or attached to along the rim of the top plate 330 below the impeller 100, is vertically coupled thereto.

In an embodiment, the electronic device cooling apparatus may be constituted to further include an inlet pipe (not shown), an outlet pipe (not shown), and a condenser (not shown), to such the vapor-liquid pump 1.

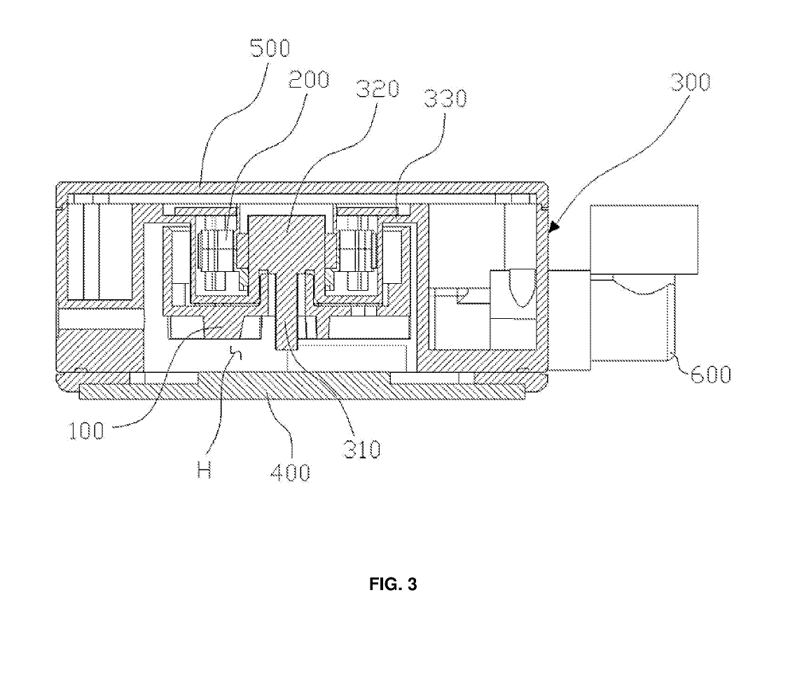

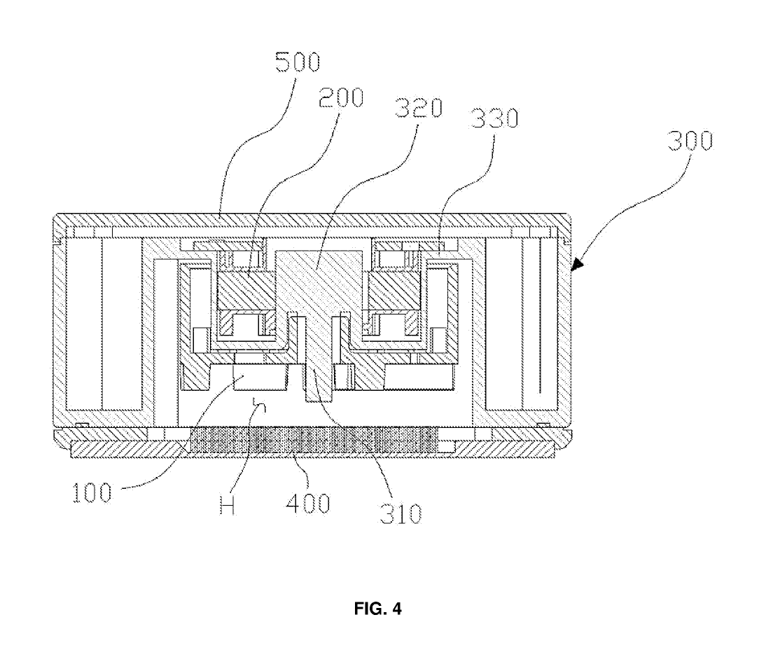

FIG. 3 and FIG. 4 are cross-sectional views taken along the B-B direction and C-C direction in FIG. 2; respectively. Hereinafter, the constitution of an electronic device cooling apparatus according to this embodiment will be described with reference to FIGS. 1 to 4.

The coolant used in the vapor-liquid pump 1 is injected in a liquid state at room temperature. However, the boiling point of the liquid changes frequently due to the changes in the temperature of the liquid according to the thermal energy of the electronic device because the vapor-liquid receiving part (H) forms a vacuum state. The vapor-liquid receiving part (H) is formed at a vacuum degree of 10-2 Torr to 10-3 Torr. In this case, some of the internal liquid evaporates to a gaseous state due to a lower boiling point at the external atmospheric pressure, and this phase change of the liquid and the gas induces the coexistence of vapor-liquid 2-phase at room temperature. However, unlike a heat pipe where a small amount of working fluid is injected, the pumping action of the vapor-liquid pump 1 may be performed smoothly by constituting the amount of liquid forming the vapor-liquid at room temperature to be in the range of 50% to 90% relative to the internal space, which is a closed loop. As the working fluid provided to the vapor-liquid pump, water may be used, and ethanol, methanol, acetone, etc. may also be used.

With regard to the sealed injection cover 300, an impeller shaft 310 which is formed internally to form an internal vacuum; a motor stator insertion rod 320 which is formed externally, and a top plate 330 expanded from the rim of the motor stator insertion rod 320 were formed in an integrated manner. In particular, the top plate 330 is formed as a recess so that the motor stator 200 inserted into the insertion rod 430 can be seated, and the edge of the impeller 100 is formed with an annular rim to enclose the recess such that the annular rim is formed to be larger than the diameter of the recess. That is, the top plate 300 is formed to be bent to be disposed between the motor stator 200 seated on the outside and the impeller 100 located inside. In this way, the inside of the motor stator 200 is formed in a closed structure, while the driving force generated in the external stator 200 can be sufficiently transmitted to the inner impeller 100. Certainly, the inner impeller 100 is provided with a ring magnet or a magnet comprised of a plurality of pieces for receiving the driving force.

Additionally, the sealed injection cover 300 is bound to the heat transfer base 400, which is fused or attached to along the expanded rim of the top plate 330 from below. In particular, the fusing or attachment may be a binding using ultrasonication, heat, or bonding. Ultimately, the sealed injection cover 300 and the heat transfer base 400 are bound and thereby form a vapor-liquid receiving part (H) inside. The heat transfer base 400 is formed by including a metal with high heat conductivity (e.g., Cu) for the conduction of heat generated in the electronic device located below, and such a metal may form a concave-convex structure inside so as to enlarge the heat radiation area.

Additionally, at one side of the sealed injection cover 300, an inlet 340 through which the vapor-liquid is flowed in and an outlet 350 through which the vapor-liquid is flowed out are formed, respectively. In particular, the inlet pipe connecting part 600 and the outlet pipe connecting part 610 can be bound to the inlet 340 and the outlet 350, respectively, and an inlet pipe and an outlet pipe can be fused or attached to the inlet pipe connecting part 600 and the outlet pipe connecting part 610, respectively.

The connection between the inlet 340, the inlet pipe connecting part 600, and the inlet pipe, and the connection between the outlet 350, the outlet pipe connecting part 610, and the outlet pipe are both sealed by fusion or attachment. This may be a binding using ultrasonication, heat, or bonding as is the case of the fusion and attachment between the sealed injection cover 300 and the heat transfer base 400, as described above.

As described above, the sealed injection cover 300 is formed such that the motor stator 200 is inserted into the motor stator insertion rod 320 above, and the motor stator 200 forms a magnetic field by providing a current, which is supplied from an external power source, to a wound coil, and thus it is desirable that the motor cover 500 be covered on top of the sealed injection cover 300.

Additionally, the impeller 100 is driven by an external driving force and thereby plays the role of pushing the vapor-liquid located in the vapor-liquid receiving part (H) to the outlet 350, and thus it is desirable that the impeller 100 be formed to have a diameter corresponding to the width of the vapor-liquid receiving part (H).

The condenser may be constituted to be located between the inlet pipe and the outlet pipe, and it is where the internal gas undergoes a phase change into a liquid due to the heat radiation to the outside. Certainly, such the condenser is not specified, and the condenser may be constituted with a large scope such that part of the inlet pipe and the outlet pipe is formed of a metal material having high thermal conductivity such as copper or aluminum.

As described above, according to an embodiment, the liquid forming the vapor-liquid performs a basic cooling action on an electronic device by its specific heat, and acts to cool the electronic device using specific heat and the latent heat of evaporation due to a phase change of the fluid by being constituted so that the fluid phase change can occur easily in a vacuum state due to a low boiling point.

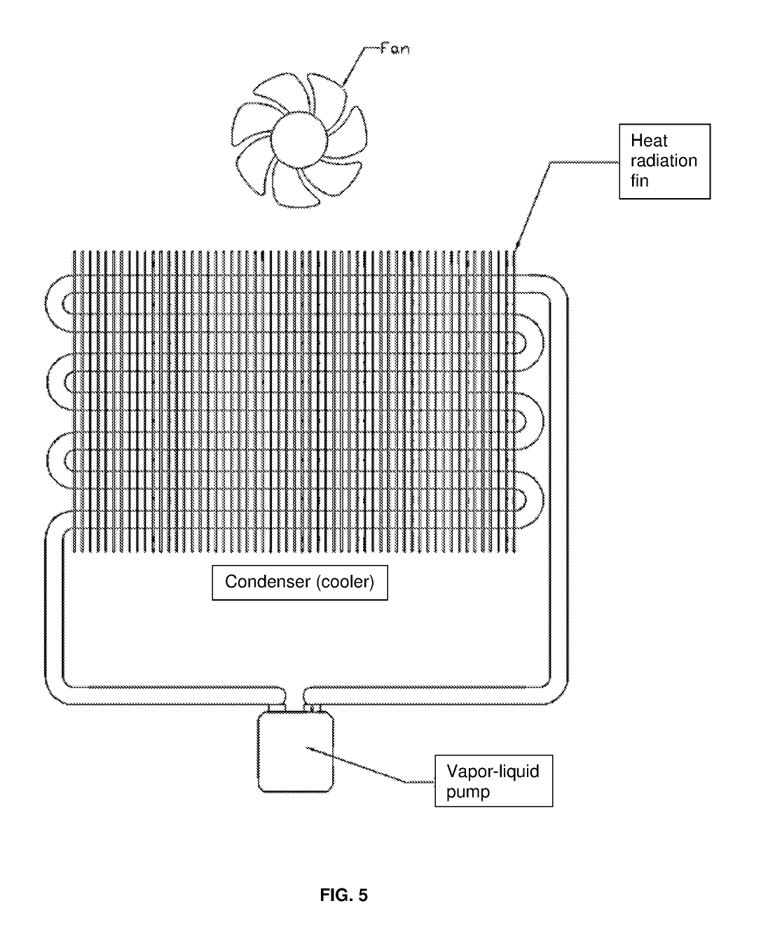

FIG. 5 is a diagram illustrating the entire system of an electronic device cooling apparatus according to an embodiment of the present invention. As illustrated in FIG. 5, the entire system of an electronic device cooling apparatus according to an embodiment of the present invention consists of a vapor-liquid pump, an inlet pipe of vapor-liquid and an outlet pipe of vapor-liquid, a heat radiation fin, and a fan. Each constitution is the same as described above, and the condenser (or cooler) may further include a heat radiation fin.

Although the present invention has been described with reference to accompanying drawings, it will be understood by those skilled in the art that the technical configurations of the present invention described above can be embodied in other specific forms without departing from the technical ideas or essential features of the present invention. It is therefore to be understood that the exemplary embodiments disclosed herein are only for illustrative purposes and should not be construed as limiting the scope of the present invention. Further, the scope of the present invention is represented by the following claims rather than the above detailed description. In addition, all changes or modifications derived from the meaning and scope of the claims and their equivalents should be construed as being included within the scope of the present invention.

### CODE EXPLANATION

1: Vapor-liquid pump
H: Vapor-liquid receiving part
100: Impeller
200: Motor stator
300: Sealed injection cover
310: Impeller shaft
320: Motor stator insertion rod
330: Top plate
340: Inlet
350: Outlet
400: Heat transfer base
500: Motor cover
600: Inlet pipe connecting part
610: Outlet pipe connecting part

What is claimed is:

1. An electronic device cooling apparatus equipped with a vapor-liquid pump, comprising:
an impeller located in a vapor-liquid receiving part that receives a vapor-liquid;
a motor stator which is located outside separated from the vapor-liquid receiving part and transfers the driving force to the impeller;
a sealed injection cover, in which an impeller shaft, which is formed to protrude to the center of the vapor-liquid receiving part such that the impeller is inserted thereinto, is formed on one side; a motor stator insertion rod, which is formed to protrude from the axis to the outer center of the impeller shaft such that the motor stator is inserted thereinto, is formed on the other side; a top plate, which is formed by extending from an edge of the motor stator insertion rod to separate the impeller from the motor stator, is formed; and an inlet through which the vapor-liquid flows in and an outlet through which the vapor-liquid flows out are formed on one side of the top plate;
a heat transfer base, which is fused or attached to the bottom of the impeller along the rim of the top plate such that the vapor-liquid receiving part is formed;
an inlet pipe, which is fused or attached to the inlet such that the vapor-liquid is flowed in;
an outlet pipe, which is fused or attached to the outlet such that the vapor-liquid is flowed out; and
a condenser, which is located between the inlet pipe and the outlet pipe and condenses the gas in the vapor-liquid,
wherein the inner space, which is a closed loop that leads to the vapor-liquid receiving part, the inlet pipe, the outlet pipe and the condenser, forms a vacuum.

2. The electronic device cooling apparatus of claim 1,
wherein the top plate forms a recess into which the motor stator is inserted and seated; and
the impeller, being formed so as to surround the recess with the top plate interposed therebetween, comprises a magnet that receives power from the motor stator.

3. The electronic device cooling apparatus of claim 1,
wherein the amount of the liquid that constitutes the vapor-liquid accounts for 50% to 90% of the internal space, which is the closed loop, at room temperature.

4. The electronic device cooling apparatus of claim 1,
wherein the liquid constituting the vapor-liquid cools the electronic device using specific heat and the latent heat of evaporation by fluid phase change.
